(19) United States
(12) Patent Application Publication
(10) Pub. No.: US 2014/0113074 A1
(43) Pub. Date: Apr. 24, 2014

(54) METHOD FOR SYNTHESIS OF LARGE AREA THIN FILMS

(71) Applicant: BLUESTONE GLOBAL TECH LTD., Wappingers Falls, NY (US)

(72) Inventors: Xuesong LI, Wappingers Falls, NY (US); Jia-Hung WU, Wappingers Falls, NY (US)

(73) Assignee: BLUESTONE GLOBAL TECH LTD., Wappingers Falls, NY (US)

(21) Appl. No.: 13/655,588

(22) Filed: Oct. 19, 2012

(51) Int. Cl. C23C 16/44; C23C 16/34; C23C 16/26

(52) U.S. Cl. 427/249.1; 427/255.28; 427/255.38

(57) ABSTRACT

Improved methods for synthesizing large area thin films are disclosed, which result in films of enhanced width. The methods comprise providing a separator material which is rolled or wound up, along with the metallic foil substrate on which the thin film is to be deposited, to form a coiled composite which is then subjected to conventional chemical vapor deposition. Optionally, a winding tool may be used to aid in the rolling process. The methods enable a many-fold increase in the effective width of the substrate to be achieved.

### TECHNICAL FIELD

The present invention relates broadly to the production of films via chemical vapor deposition, and in particular, to methods for forming carbon films and other films using such deposition. More specifically, this invention relates to an improved method for processing a substrate prior to heating in a reactor chamber in order to form a large area thin film having an augmented width dimension.

### BACKGROUND OF THE INVENTION

Graphene and boron-nitride films are examples of useful large area thin films that may be beneficially produced using the methods of the present invention. The invention is particularly useful in the synthesis of graphene, which is a one-atom thick, two-dimensional planar sheet or monolayer in which carbon atoms are bonded in a stable extended fused array, comprising polycyclic aromatic rings with covalently bonded carbon atoms having sp² orbital hybridization. The covalently bonded carbon atoms are densely packed in a honeycomb crystal lattice, and may form a 6-membered ring as the basic repeating unit, but 5-membered rings and/or 7-membered rings may also be formed. Graphene has distinctive electrical, mechanical and chemical properties that make it attractive for applications in flexible electronics. For example, electrons may move on a graphene sheet as though they have zero mass, and thus may move at the velocity of light.

Graphene may be formed on the surface of a substrate by a variety of methods. An exemplary but promising method is set forth in U.S. Patent Application Publication No. 2011/0091647 (the disclosure of which is incorporated by reference herein in its entirety), in which graphene may be produced using a chemical vapor deposition (CVD) process. In general, CVD is a process by which a thin film layer is deposited onto a substrate. The substrate is supported in a vacuum deposition process chamber, and the substrate is heated to a high temperature, typically several hundred degrees Celsius. Deposition gases are then injected into the chamber, and are thermally activated such that a chemical reaction takes place by which a thin film layer is deposited onto the substrate. The substrate on which the thin film layer has been deposited is then cooled to room temperature, after which the thin film layer may be separated from the substrate.

The aforementioned U.S. Patent Application Publication No. 2011/0091647 discloses a CVD process by which graphene may be formed on a flat metallic substrate such as copper foil, which is heat-treated in the presence of a gaseous carbon source, specifically, a mixture of a hydrocarbon gas and hydrogen gas. The metallic foil substrate is loaded into a tube furnace, usually comprising a cavity where the heat treatment is carried out at a specified temperature; the cavity is generally surrounded by heating elements and is in fluid communication with the gaseous sources. During the treatment, a thin carbon film (graphene) is formed on the surface of the metallic foil substrate, due to the decomposition of the hydrocarbon gas, which is typically methane. After a specified period of time the heat treatment is terminated, and the furnace, along with the coated substrate, is then cooled to room temperature, after which the thin carbon film may be used directly, with the substrate still attached, or it may be separated or transferred from the substrate in a known manner, and then used.

In a similar manner, thin films of boron-nitride can be obtained by CVD, from precursors such as boron trichloride or boron tribromide and either nitrogen or a source of nitrogen such as ammonia, using a metallic foil substrate. Moreover, in addition to utilizing conventional CVD, graphene films, boron-nitride films and other large area thin films can alternatively be produced using other related processes, such as plasma-enhanced CVD (PECVD), as well as by using similar processes such as atomic layered deposition (ALD).

In each of these production techniques, the size (i.e., the surface area) of the thin film that is produced is determined by the size of the substrate on which it is grown, and the latter is limited, in turn, only by the dimensions of the reactor chamber or cavity of the CVD apparatus that is used. In general, that chamber is a horizontally-oriented cylindrical quartz tube, and the dimensions of the substrate which may be used are circumscribed by the dimensions of the chamber—the length of the substrate, which is defined as the dimension parallel to the axis of the cylindrical chamber, is determined by the length of that portion of the chamber which can be heated (that is, by the length of the heating zone of the furnace), and the width of the substrate, which is defined as the dimension perpendicular to the length and which is parallel to a radial dimension of the cylindrical chamber, is determined by the diameter of the chamber (that diameter being about equal to the maximum substrate width that can be obtained when the conventional technique of placing a flat sheet of the substrate into the cylindrical chamber is utilized). Although there are relatively few technical difficulties involved in manufacturing very long quartz tubes, and in manufacturing tube furnaces that would accommodate such tubes, the difficulty in manufacturing larger diameter quartz tubes increases dramatically with the increase in diameter of the tube. In addition, the connections between the quartz tube and the surrounding metal parts become more problematic with increased diameters because the manufacturing errors in the size and/or roundness of the quartz tube become magnified. Therefore, there are practical limits as to the diameter of the quartz tube reactor chamber which limit the width of the substrate that may be utilized therein, and which in turn limit the width of the thin film that can be produced.

Accordingly, a technique by which to load a metallic foil substrate into the quartz tube reactor chamber, such that the width of the substrate, and therefore the width of the thin film subsequently produced, can be increased dramatically despite the limits imposed by the diameters of presently-existing reactor chambers for CVD furnaces, would be a useful addition to the technology by which such films are manufactured using CVD or similar processes. Yet, despite the existence and availability of CVD processes for many years, such a technique has eluded researchers.

Although efforts have been made in the prior art to provide such techniques, those efforts are not completely satisfactory. For example, the prior art includes a technique by which the substrate can be wrapped around a cylindrical holder, but this provides an increase in substrate width of only about three times that of the chamber diameter itself. Moreover, although the aforementioned U.S. Patent Application Publication No. 2011/0091647 appears to disclose that a copper foil substrate about 2 meters in width may be utilized in the production of graphene, thus implying that the graphene film produced could have a comparable width, it has been determined that a flat substrate of such a width dimension would not be workable as a practical matter, and/or would result in higher cost, due to the manufacturing and other difficulties mentioned above that are associated with producing quartz tube reactor chambers of increased diameter.

It is therefore the principal object of the present invention to provide improved methods for synthesizing large area thin films using a CVD or CVD-type furnace, in which the width dimension of the thin film produced may be greatly increased.

### SUMMARY OF THE INVENTION

This and other objects of the present invention are achieved by providing, along with a metallic foil substrate on which a large area thin film is to be formed, a layer or mat of a substantially flat separator material, the length and width dimensions of which are chosen to correspond substantially to that of the metallic foil substrate. The mat is positioned adjacent to and overlying one surface of the substrate and, together with the substrate, is then rolled up or wound up to form a substantially cylindrical coiled composite in which the layer of separator material is interleaved between adjacent layers of the metallic foil substrate. This cylindrical coiled composite may then be placed within the conventional reactor chamber of a CVD or CVD-type furnace, and may be subjected to the customary heat treatment, following which the coiled composite (after cooling) may be withdrawn from the furnace and unrolled, and the mat of separator material removed, leaving the substrate, now coated with a thin film, for subsequent use and/or further manipulation using known techniques. By utilizing this procedure, thin films of enhanced width, as compared with the width of the CVD reactor chamber itself, may easily be formed.

Thus, the present invention generally concerns improved methods for thin film synthesis. In one aspect of the invention, a method for synthesizing a large area thin film is provided, the method comprising the steps of providing a substrate for thin film synthesis, providing a separator material, positioning the separator material in a substantially overlying relationship with the substrate to form a composite, winding the resulting composite so as to form a substantially cylindrical coiled body, positioning the cylindrical coiled body in a reaction chamber, and generating a large area thin film on the substrate via a CVD reaction.

In another aspect of the invention, an improvement in the prior art method of synthesizing a large area thin film is provided, the prior art method comprising the steps of heating a substantially flat substrate, forming a thin film on a surface of the substrate by exposing the substrate to chemical vapor deposition, and cooling the substrate to room temperature, the improvement comprising, prior to the heating step, providing a separator material, positioning the separator material adjacent to and in a substantially overlying relationship with the substrate to form a composite, and winding the composite so as to provide a coiled substrate on which to form a thin film.

### BRIEF DESCRIPTION OF THE DRAWINGS

These and other aspects, features, objects and advantages of the present invention will become more apparent to those skilled in the art from the following detailed description of the presently most preferred embodiments thereof (which are given for the purposes of disclosure), when read in conjunction with the accompanying drawings (which form a part of the specification, but which are not to be considered as limiting its scope), wherein:

FIG. 1 is a diagrammatic view depicting the process by which a thin film such as graphene is conventionally deposited on a surface of a substantially flat metallic foil substrate in the reactor chamber of a CVD device;

FIGS. 2-4 are enlarged schematic perspective views of a preferred embodiment of the present invention, showing a separator material overlying one surface of a metallic substrate, and also depicting the rolling or winding of the separator material together with the metallic substrate so as to form a cylindrical coiled composite, along with a tool used to effectuate the winding; and

FIG. 5 is a view substantially similar to that of FIG. 1, depicting a cylindrical coiled composite, formed in accordance with the present invention, positioned within the reactor chamber of a CVD device for deposition of a thin film onto the metallic foil substrate.

### DETAILED DESCRIPTION OF THE PREFERRED EMBODIMENT

The preferred and other embodiments of the present invention will now be further described. Although the invention will be illustratively described hereinafter with reference to the formation of a large area graphene film on a copper foil substrate in a conventional CVD furnace, in the manner described generally in U.S. Patent Application Publication No. 2011/0091647, it should be understood that the invention is not limited to the specific case described, but extends also to the formation of boron-nitride and other large area thin films, utilizing other metallic foils (including nickel foils or aluminum foils) or other substrates, and using alternative vapor deposition processes such as PECVD or ALD.

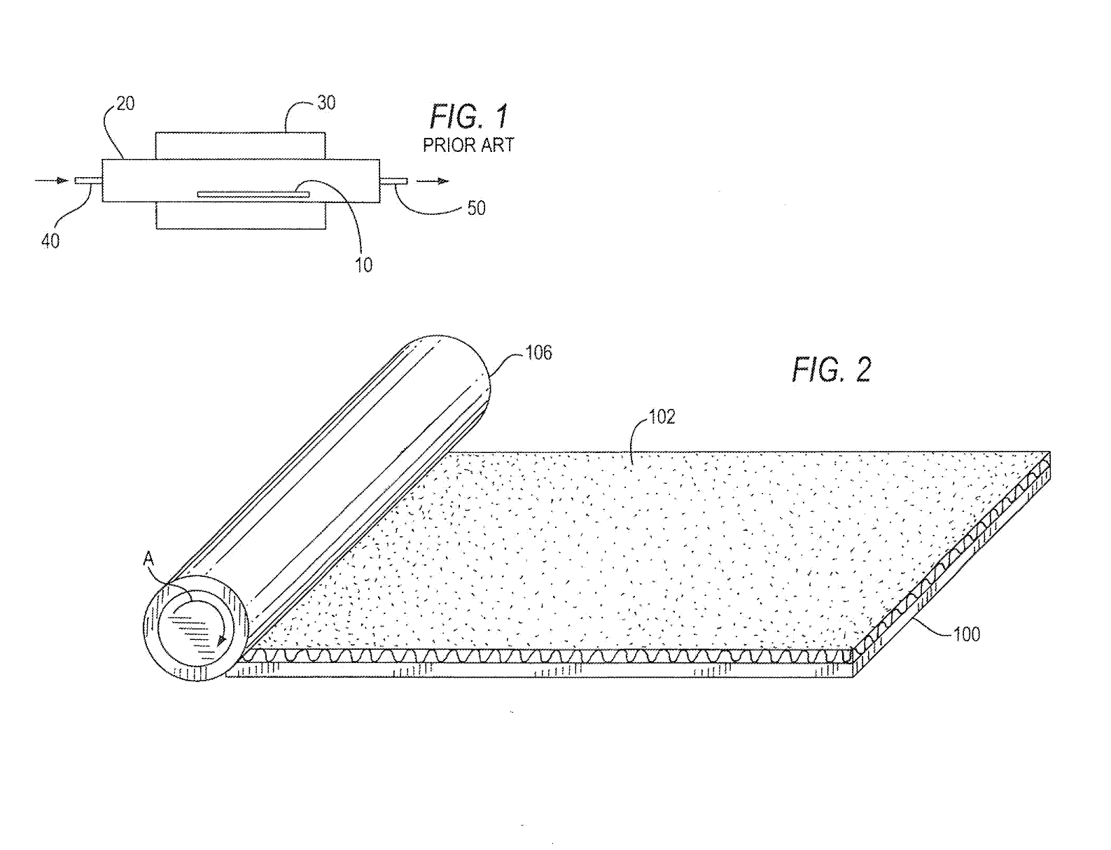

Referring first to FIG. 1, the conventional prior art process by which a thin film such as graphene may be deposited on a surface of a flat substrate 10 in the reactor chamber 20 of a CVD furnace 30 having a gas inlet 40 and a gas outlet 50, in the manner described generally in U.S. Patent Application Publication No. 2011/0091647, is depicted diagrammatically, but for ease of illustration, the substrate holder, heating elements and other components of a conventional CVD furnace have been omitted. It is to be understood that, except for the configuration of the substrate, the present invention utilizes the same conventional process.

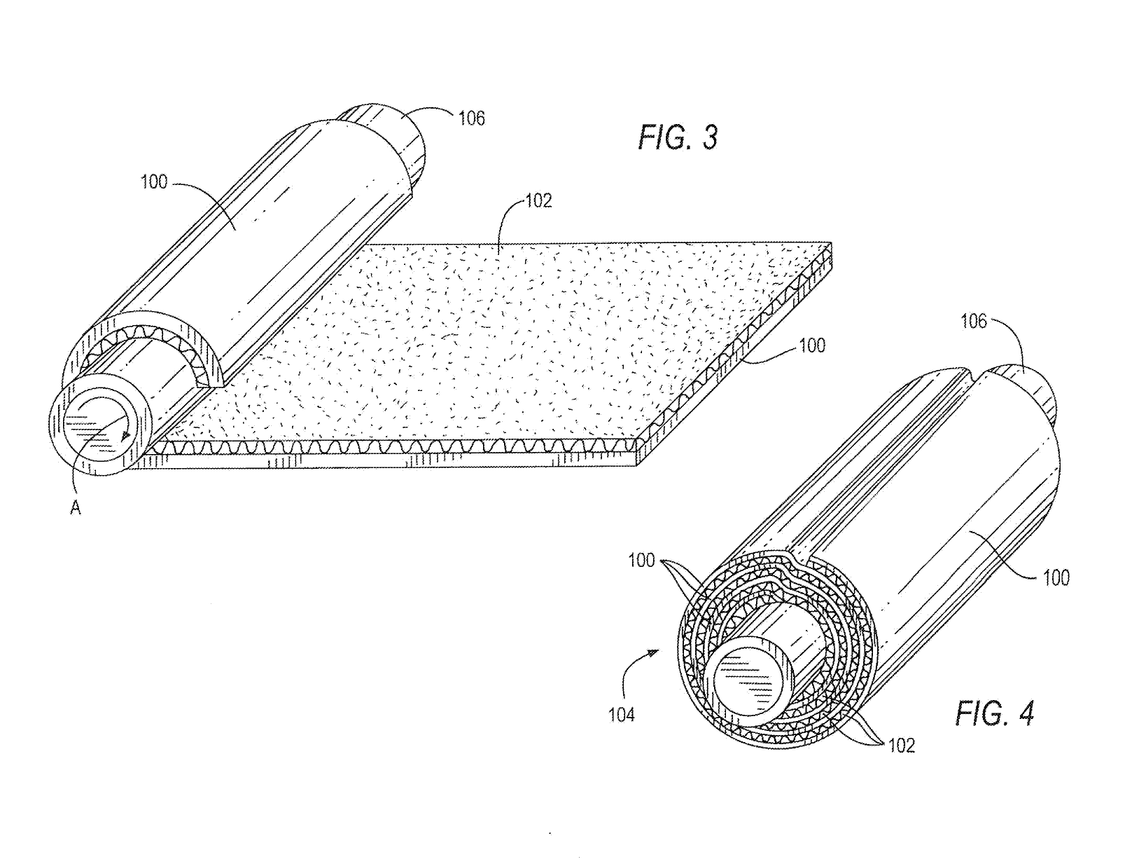

Referring now to FIGS. 2-4 in addition to the aforementioned FIG. 1, a preferred embodiment of the present invention will now be described. A copper foil substrate, having a thickness in the range of 10 μm-100 μm, and on the surfaces of which a large area thin film is to be formed, is generally designated 100. Initially, the copper foil substrate 100 is substantially flat, as can be seen in FIG. 2. A layer or mat of a separator material 102, which also is initially substantially flat, is positioned adjacent to and substantially overlying one surface of substrate 100, the length and width dimensions of separator material 102 being chosen so as to correspond substantially to that of substrate 100.

In general, separator material 102 should be fabricated of a substance which has a melting point greater than about 1,100 degrees Celsius, and which is also inert, i.e., which does not react with substrate 100, and does not interfere with or affect the growth of graphene on the surfaces of substrate 100. Separator material 102 should be chosen to have a thickness in the range of from approximately 0.1 mm to approximately 2 mm, but within that range, it should be as thin as possible.

Separator material 102 is composed most preferably of fused quartz wool or felt, which has a consistency similar to that of cotton, and which is provided in the form of a mat that is substantially flat and that can be cut to the proper size. An acceptable quartz wool product is available commercially from Technical Glass Products, Inc., located in Painseville Twp., Ohio, U.S.A., which markets this material under the product name Coarse 9 μm Nominal Wool (CQ-wool-1.1). Other quartz products in mat form which may be used as alternatives to fused quartz wool or felt include high purity quartz fabrics or cloths, which are available commercially, in a variety of different weights, sizes, thicknesses, weaves, and fiber configurations, from Fiber Materials, Inc., of Biddeford, Me., U.S.A.

Separator material 102 may alternatively be composed of preferred substances other than fused quartz, such as high-temperature textile fabrics, including silica fabrics. An acceptable amorphous silica fabric is commercially available from AVS Industries LLC of New Castle, Del., U.S.A., under the product name ULTRAFLX silica fabric, product numbers HT84CH or HT188CH. As an additional preferred alternative to quartz, separator material 102 may be composed of a thermal insulation such as the ultra high temperature flexible ceramic insulation which is commercially available in roll form, in a variety of lengths, thicknesses and densities, under product numbers which commence with the designation 93315K, from McMaster-Carr Supply Company, based in Elmhurst, Ill., U.S.A.

After separator material 102 is positioned as shown in FIG. 2, it is rolled up or wound up together with substrate 100, as shown in FIGS. 3-4, so as to form a substantially cylindrical coiled composite 104, in which a layer of separator material 102 is interleaved between adjacent layers of substrate 100. Although the cylindrical composite 104 can be formed by hand, without the use of an aid, optionally a winding tool 106 may be used as to aid in the rolling or winding process. Winding tool 106 is preferably substantially cylindrical in shape, and can take the form of either a solid rod or a hollow tube, although other, non-cylindrical shapes may alternatively be used effectively.

In order to facilitate grasping winding tool 106 for rotation, its length should generally be chosen so as to be approximately 10 cm greater than the corresponding dimension of separator material 102 and/or substrate 100, thereby enabling winding tool 106 to be positioned such that a portion extends out and away from separator material 102 by approximately 5 cm on either side. Then, separator material 102 may be wound up, along with substrate 100, by grasping the extended portions of winding tool 106 on either side, and by turning or rotating it (e.g., by spinning, winding or twirling), in the direction indicated by arrows A in FIGS. 2-3, either manually or with the aid of a mechanical spinning device, until a substantially cylindrical coiled composite body 104 is formed, with winding tool 106 positioned at its core.

Winding tool 106 is preferably comprised of fused quartz, and hollow fused quartz tubes, as well as solid fused quartz rods, which are acceptable for use as winding tool 106 are available commercially from Technical Glass Products, Inc., located in Painseville Twp., Ohio, U.S.A., which markets a wide variety of such items. Most preferably, a hollow fused quartz tube having an inner diameter of 8 mm and an outer diameter of 10 mm is used when the reactor chamber or cavity of the CVD apparatus that is to be used has a 2-inch diameter, while a hollow fused quartz tube having an inner diameter of 46 mm and an outer diameter of 50 mm is used when the reactor chamber has a 5-inch diameter, although hollow fused quartz tubes having inner diameters between 8 mm and 46 mm and outer diameters between 10 mm and 50 mm may be used as well, depending on the size of the reactor chamber. If a solid fused quartz rod is to be used instead of a hollow tube, then most preferably a solid fused quartz rod having a 10 mm diameter is used when the reactor chamber has a 2-inch diameter, while a solid fused quartz rod having a 40 mm diameter is used when the reactor chamber has a 5-inch diameter, although solid fused quartz rods having diameters between 10 mm and 40 mm may be used as well, depending on the size of the reactor chamber.

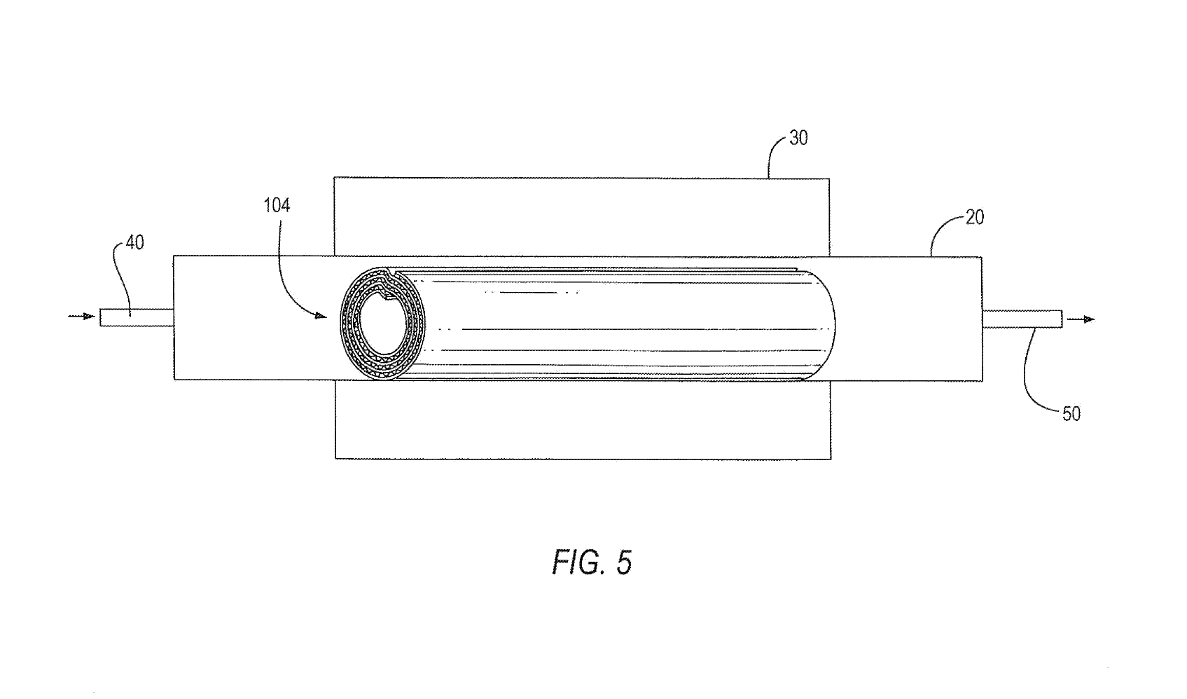

Referring now to FIG. 5 in addition to the aforementioned FIGS. 1-4, following the rolling or coiling step, the winding tool 106 (if any) is removed from the core of cylindrical coiled composite 104 by sliding it laterally (the removal step is not shown in the drawings), and coiled composite 104 may then be placed into the reactor chamber 20 of a CVD furnace 30 so as to allow a graphene coating (not shown in the drawings) to be deposited onto the surfaces of substrate 100 using a CVD process.

Following the deposition of the graphene coating, removal of the cylindrical coiled composite 104 from the CVD furnace, and cooling, the coiled composite may be unrolled by hand, and separator material 102 may be removed (these steps are not shown in the drawings). Depending upon the durability of separator material 102 and the degree of its contamination from the metallic substrate, separator material 102 may be re-used, perhaps as many as 20-30 times, following which it should be discarded. After separator material 102 is removed, the graphene coating on substrate 100 may be used, either directly with substrate 100 still attached, or it may first be separated or transferred from the surfaces of substrate 100 in a known manner (for example, a salt solution which is an oxidizing agent may be used to exfoliate the graphene coating from the substrate), following which the separated graphene layers may be utilized in a graphene application or otherwise further processed for ultimate use.

The enhanced width of the thin film that can be synthesized using the process of the present invention may be calculated according to the following equation:

$$W = \frac{π ( {D}^{2} - {d}^{2} )}{4 ( t + {t}^{′} )}$$

wherein:

D=the inner diameter of the CVD reactor chamber;

d=the outer diameter of winding tool 106 (if not used, then d=0);

t=the thickness of separator material 102; and

t′=the thickness of substrate 100.

Thus, as an example, if the inner diameter of the reactor chamber or cavity of the CVD apparatus is 46 mm, and if the outer diameter of winding tool 106 is 10 mm, the thickness of separator material 102 is 2 mm, and the thickness of substrate 100 is 0.025 mm, then a thin film of having a width of 782 mm may be produced, which is approximately 16 times wider than the diameter of the reactor chamber of the CVD apparatus. As a further example, if the inner diameter of the reactor chamber is 125 mm, and the values for the other three variables remain the same, then a thin film of having a width of 6,021 mm may be produced, which is approximately 48 times wider than the diameter of the reactor chamber. These examples illustrate that the invention provides a facile process by which thin films of enhanced width, as compared with the width of the reactor chamber itself, may be formed.

While there has been described what are at present considered to be the preferred embodiments of the present invention, it will be apparent to those skilled in the art that the embodiments described herein are by way of illustration and not of limitation. Various modifications of the disclosed embodiments, as well as alternative embodiments of the invention, will become apparent to persons skilled in the art upon reference to the description of the invention. Therefore, it is to be understood that various changes and modifications may be made in the embodiments disclosed herein without departing from the true spirit and scope of the present invention, as set forth in the appended claims, and it is contemplated that the appended claims will cover any such modifications or embodiments.

1. (canceled)

2. (canceled)

3. (canceled)

4. (canceled)

5. (canceled)

6. (canceled)

7. (canceled)

8. (canceled)

9. (canceled)

10. (canceled)

11. In a method for synthesizing a thin film using chemical vapor deposition, said method comprising the steps of heating a substantially flat substrate, forming a thin film on a surface of said substrate by exposing the substrate to chemical vapor deposition, and cooling the substrate to room temperature, the improvement comprising, prior to said heating step, providing a separator material, positioning said separator material adjacent to and in a substantially overlying relationship with said substrate to form a composite in which a layer of separator material is interleaved between adjacent layers of said substrate, and winding said composite so as to provide a coiled composite;
wherein the thin film is selected from the group consisting of graphene and boron nitride.

12. The method of claim 11 wherein said separator material is comprised of a substance selected from the group consisting of fused quartz wool, ceramic insulation and a silica fabric.

13. The method of claim 12 wherein said separator material is provided in the form of a substantially flat mat, and wherein the thickness of said mat is in the range of from approximately 0.1 mm to approximately 2 mm.

14. The method of claim 13 wherein said separator material is comprised of fused quartz wool.

15. The method of claim 11 wherein the winding step is accomplished with the aid of a winding tool.

16. The method of claim 15 wherein said winding tool is comprised of fused quartz.

17. The method of claim 16 wherein said winding tool is substantially cylindrical in shape, and wherein the form of said winding tool is selected from the group consisting of a hollow tube and a solid rod.

18. (canceled)

19. The method of claim 19 wherein the substrate is comprised of a metallic foil.

20. The method of claim 19 wherein the thin film is graphene, and wherein said metallic foil is comprised of copper.
